(19) United States
(12) Patent Application Publication
(10) Pub. No.: US 2011/0006756 A1
(43) Pub. Date: Jan. 13, 2011

(54) POWER MEASUREMENT SYSTEM, METHOD AND/OR UNITS

(75) Inventors: Neil Alexander Rosewell, Cambridgeshire (GB); Nicholas George Bailey, Cambridge (GB); James Mark Carson England, Cambridge (GB); Edward Grellier Colby, Cambridge (GB)

Correspondence Address: THORPE NORTH & WESTERN, LLP., P.O. Box 1219, SANDY, UT, 84091-1219, US

(73) Assignee: SENTEC LIMITED, Cambridge (GB)

(21) Appl. No.: 12/921,149

(22) PCT Filed: Mar. 4, 2009
(86) PCT No.: PCT/GB09/00603

§ 371 Date: Sep. 3, 2010

(30) Foreign Application Priority Data
Mar. 4, 2008 (GB) 0803983.6

(51) Int. Cl. G01R 19/145

(52) U.S. Cl. 324/140 R

(57) ABSTRACT

The invention provides a system (1) for providing power measurements using a current sensing element (2) located at a supply line and a voltage sensing element (3) located remotely from said supply line location. Power measurement is enabled by using a communications link (4) to correlate current and voltage measurements.

### FIELD OF THE INVENTION

This invention relates to the field of energy use monitoring, particularly but not exclusively for use as an in-home energy monitor system.

### BACKGROUND TO THE INVENTION

A number of home energy monitors exist, consisting of a sensor clamped around one of the electricity meter tails, to measure the current drawn by the household. An estimate of the power consumption is calculated using the measured current data and assumptions regarding the supply voltage waveform. Significantly better accuracy can be achieved by measuring the supply voltage as well as the current. Variations in supply voltage and power factor can be accounted for, leading to a significant improvement in the measured power use.

Traditionally voltage measurement requires an in-line sensor, installation of which would need to be performed by a qualified electrician.

A standard domestic electricity meter is typically placed in series with the incoming supply, and is therefore able to directly measure both current and voltage usage and hence log the total power used.

GB 227,417,1A describes an electric power monitoring device. U.S. patent application number 2006/0241880 A1 describes an energy monitoring device which includes means for sensing current in a power line.

With a system that only measures current, assumptions must be made about the voltage in order to calculate the power consumed, and variations in power factor of the system being monitored will cause significant differences between the number of kWh recorded by different devices. Therefore a home energy monitor that only measured current would be likely to disagree with the main meter for that home. It is likely that this difference will exceed 5%, at which point a customer would note the difference and lose confidence in one display or the other.

Measurement of both voltage and current at the same position is often difficult, as direct electrical connection to the wires would be necessary for voltage measurement. In a domestic environment it is unlikely that a socket, from where voltage could be measured, is present. A qualified electrician would therefore be required to install any monitor that did need to measure voltage, leading to increased inconvenience and expense for customers. So that the user has easy access to the information recorded by the monitor, it may also be necessary to run wires from the current sensor to a display in a more convenient location, away from the sensor unit, causing further inconvenience.

Therefore, an energy monitor which can accurately measure power and is easy to install would be an improvement over the art.

### SUMMARY OF THE INVENTION

The invention provides a system for providing accurate power measurements using a current sensing element for sensing current at a supply line location and a voltage sensing element located remotely from said supply line location. Power measurement is enabled by using a communications link to correlate current and voltage measurements. This allows the correct power consumption to be calculated as the supply voltage and load power factor change.

The invention further provides a method for providing accurate power measurements. The method comprises providing a current sensing element and a voltage sensing element and: measuring current in a supply line using the current sensing element; measuring voltage in a location remote from said supply line location using the voltage sensing element; and using a communication link to correlate current and voltage measurements.

In this way the invention provides devices, a system or a method which can be used to monitor current and voltage separately, allowing the devices to be placed for greater convenience and efficiency by the user.

Typically, the supply line will branch between the current sensing element and the voltage sensing element, such that the voltage sensing element is located on one of the branches.

In a presently preferred embodiment, the communications link is a wireless communications link.

An energy monitor system preferably measures both current and voltage and is easy to install. This might involve some current sensor clamped to the meter tail, with a battery powered transmitter which sends average current values to a remote voltage measure and display plugged into a domestic socket. However, an average reading of voltage multiplied by an average reading of current will not yield an accurate reading, due to variations in Power Factor. In a preferred embodiment, the current and voltage is measured at the same time, or with a known discrepancy between measurements. Therefore the communications link is preferably used to synchronise the timing between current and voltage measurements.

The voltage within the installed wiring at any one point in a house will be substantially the same, and of the same phase, as the wiring at any other point. The current, however, varies and the only point at which it can be measured and considered for the whole house is before it is split at the consumer unit, leading to the necessity for the current sensor to be located at this position.

A device, system or method according to the invention can be installed in a house, or in factories, commercial premises or any other location that is supplied with electrical power.

In a presently preferred embodiment of the invention, the voltage and current sensing elements measure the current and voltage periodically. This reduces the power used by the system.

Typically, the current sensing element comprises a current clamp. It may be that the current sensing element comprises a current transformer. These devices can often be installed easily by people without special skills or equipment. Alternatively, the current sensing element may measure current by measuring the voltage drop across a fixed resistive load.

Typically, the voltage sensing element will comprise a connector suitable for use with a standard electrical outlet. This connector may be a plug. The voltage sensing element may comprise a further connector suitable for connecting a further electrical device, so that the further electrical device can draw electrical power from the standard electrical outlet through the voltage sensing element. The further connector may be a socket.

It may be that the system or method comprises an additional separate element capable of communicating with the voltage sensing element, the current sensing element or both. The additional separate element may be a personal computer. The additional separate element may be capable of wireless communication, for example with the voltage sensing element, the current sensing element, or both. It may be that the timing between the current and the voltage measurements is correlated using a signal sent by the additional separate element.

Typically, however, the timing between the current and voltage measurements is correlated using a signal sent by the current sensing element. This means that the current sensing element need not always be activated and listening for a signal, which helps to conserve power. As the current sensing element will often be powered by a battery, reducing its power consumption is important. For similar reasons, the power usage is often calculated at the voltage sensing element. Where desirable however, the signal and the calculations can be executed by any element, including the current sensing element, the voltage sensing element, or an additional separate element.

In a further aspect, the invention provides a method for providing power measurements, the method comprising providing a current sensing element and a voltage sensing element and:
measuring current in a supply line using the current sensing element;
measuring voltage in a location remote from said supply line location using the voltage sensing element; and
correlating the current and voltage measurements via a communications link.

In a subsidiary aspect, the supply line branches between the current sensing element and the voltage sensing element; the method further comprises the step of locating said voltage sensing element on one of the branches.

In a further subsidiary aspect, the communications link is a wireless communications link.

In a further subsidiary aspect, the method further comprises the step of synchronising the timing between current and voltage measurements.

In a further subsidiary aspect, the current sensing element comprises a current clamp.

In a further subsidiary aspect, the current sensing element comprises a current transformer.

In a further subsidiary aspect, the current sensing element comprises a so called Rogowski coil.

In a further subsidiary aspects, the method further comprises the step of measuring the voltage drop across a fixed resistive load to measure current.

In a further subsidiary aspect, the method further comprises the step of employing an additional separate element capable of communicating with the voltage sensing element, the current sensing element or both.

In a further subsidiary aspect, the method further comprises the step of configuring said additional separate element for wireless communication.

In a further subsidiary aspect, the method further comprises the step of correlating the current and voltage measurements by sending a signal from said additional separate element.

In a further subsidiary aspect, the method further comprises the step of correlating said current and voltage measurements by sending a signal from said current sensing element.

In a further subsidiary aspect, the method further comprises the step of calculating said power usage at the voltage sensing element.

In a further independent aspect, the invention provides a power measuring unit comprising:
an element suitable for measuring voltage;

a receiver for wirelessly receiving signals representative of current measurements; and

a power calculator for calculating power based on said measured voltage and said wirelessly received signals representative of current measurements.

The invention also includes software which configures components to operate according to the needs of any of the methods described above.

In a further independent aspect, the invention provides a system for providing accurate power measurements using separate voltage and current sensing elements that are located remotely from one another. Accurate power measurement is enabled by using a wireless communications link to synchronise the timing between current and voltage measurements. This allows the correct power consumption to be calculated as the supply voltage and load power factor change.

In a subsidiary aspect, the method uses other measurements to calculate electricity usage.

In a subsidiary aspect, the method uses any voltage measurement, including but not limited to direct electronic measurement.

In a further subsidiary aspect, the method envisages sending transmission by any means, including but not limited to radio link, optic fibre, power line modulation or direct cable connection.

In a further subsidiary aspect, the method envisages synchronisation which allows the measurements to be taken at the same time, or at a known or measured time gap, then combined for power measurement.

### BRIEF DESCRIPTION OF THE DRAWINGS

An embodiment of the invention will now be described, by way of example only, and with reference to the accompanying drawings, in which:

FIG. 1 is a block diagram showing a first power monitoring system according to the invention;

FIG. 2 shows a current sensor;

FIG. 3 shows a voltage sensor;

FIG. 4 is a graph showing a synchronisation signal; and

FIG. 5 is a block diagram showing a second power monitoring system.

### DETAILED DESCRIPTION OF EXEMPLARY EMBODIMENTS

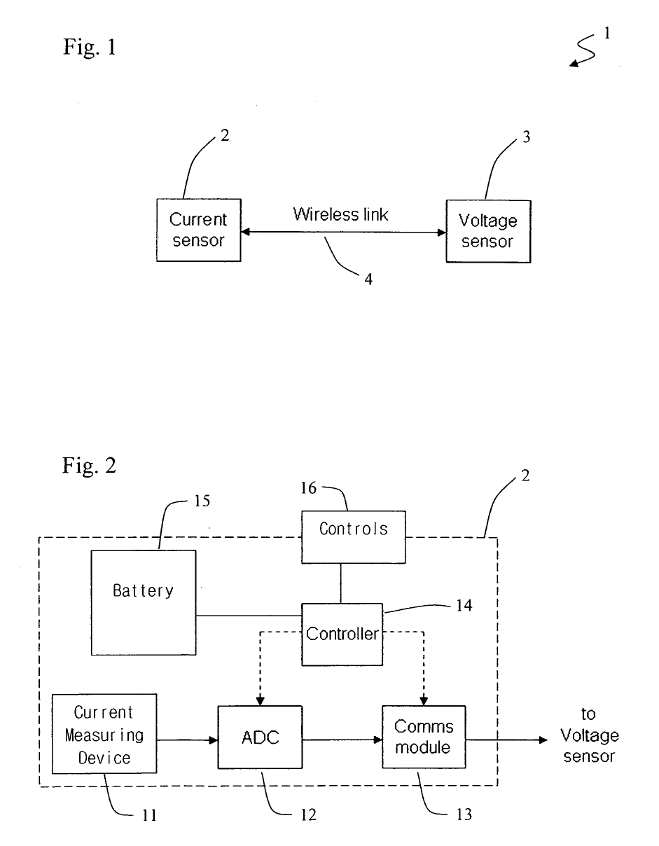

FIG. 1 shows a first power monitoring system I consist of two physically separate elements for measuring the current and voltage. The power monitoring system 1 comprises a current sensor 2 and a voltage sensor 3. The power monitoring system is provided with a method for synchronising the timing of current and voltage measurements. The current sensor 2 and the voltage sensor 3 are connected over a wireless link 4.

FIG. 2 shows the current sensor 2 in detail. The current sensor 2 element of the power monitoring system 1 consists of a clamp-on current transformer, measurement electronics and a wireless communications module, all of which is battery powered. The sensor is clamped around one of the electricity meter tails within the meter cupboard and measures the current drawn by the metered load. The current waveform is sampled over a set period of time, the sampled data being transmitted to the voltage sensing element once it has been acquired.

The current sensor 2 comprises a current measuring device 11, which can be clamped around a power line to measure the current passing through that power line. This is easy to install, and can be fastened into place even by someone who is not a qualified electrician as no exposure of live wires is necessary. The current measuring device samples the current in the power line periodically. The measurements made by the current measuring device 11 are passed to a first ADC (Analogue to Digital Converter) 12, which converts the analogue signal to a digital one. The digital signal is then passed to the first communication module 13 which transmits the information wirelessly to the voltage sensor 3.

The current sensor 2 also comprises a first controller 14 and a battery 15. In order to conserve battery power the sampling is performed periodically over a short time window. Typically the current would be sampled over a few line cycles once a second. This allows the electronics within the current clamp to be in a low power state for the majority of the time, thus extending battery life. Low power consumption can be achieved by sampling for shorter windows or at longer intervals at the expense of reducing the accuracy of the subsequent power measurement. However, by measuring the voltage as well as the current the overall system can achieve better accuracy than those systems that only measure the current.

The current measuring device 11 works by measuring inductive effects in a ferrite coil. This is a suitable technique for measuring an alternating current, but will not work with direct currents. If an embodiment of the invention is used to monitor a direct current, or if greater accuracy is required, then other current measuring devices can be used, for example hall effect current measuring devices.

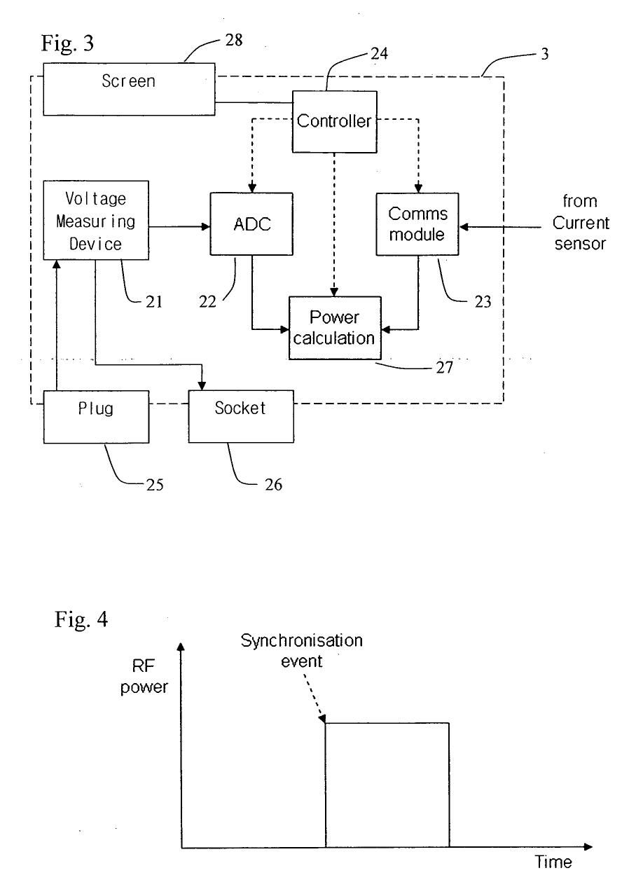

FIG. 3 shows the voltage sensor 3 in detail. The voltage sensor element 3 of this power monitoring system consists of a unit that plugs directly into a standard power socket outlet. The sensor unit consists of measurement electronics and a wireless communication module. The voltage sensor 3 comprises a voltage measuring device 21 that samples the voltage of the line to which it is attached, a second ADC 22 for converting the resultant analogue signal into a digital signal, a second communications module 23 for receiving information wirelessly from the current sensor 2, and a second controller 24. The second voltage measuring device 21 is attached to a plug 25 which is suitable for attaching to a standard electrical outlet. The voltage sensor 3 draws the power it uses to operate from this plug 25. The voltage sensor 3 further comprises a standard electrical socket 26. The electrical socket 26 allows other electrical devices to be attached to the electrical outlet through the voltage sensor 3 and operate in the usual way.

Optionally, the voltage waveform present at the socket outlet is sampled over the same time period as the current waveform sampling and at the same periodic intervals. Other correlations of current and voltage measurements are envisaged for example: the voltage sampling rate may be lower than the current sensing rate eg. every 10 minutes provided the corresponding current measurement can be identified.

The voltage sensor element 3 can also draw power from the socket and so does not need to be battery powered. For this reason the voltage sensor element 3 is used to perform the calculation of power consumption, which requires more processor power than just measuring the current or voltage waveforms. The calculation of power consumption is performed by the power calculation module 27 and can be displayed on a screen 28 set into the front of the voltage sensor 3.

In order to achieve accurate power measurements the time windows over which voltage and current are sampled are preferably synchronised. Synchronisation is achieved using the wireless communications channel. One node in the system transmits a synchronisation message that both the current and voltage sensor elements receive at the same time. This message is used to synchronise timers within each sensor element. The start of the sampling window occurs at a predetermined time after the synchronisation message event. A synchronisation message is sent at periodic intervals and determines the intervals at which sampling takes place.

Synchronisation is achieved by detecting the start or end of the transmission of the synchronisation message over the wireless communications channel. By detecting the presence of power within the radio frequency band of the communications channel the timing of the synchronisation message can be measured to within the required accuracy at both voltage and current sensor elements. Starting the sampling window a predetermined time after the synchronisation event allows the synchronisation message to be processed to ensure that it is the expected message, thus validating the timing capture from the physical radio frequency channel.

Although any node within the power monitor system can send the synchronisation message, it is sent from the current sensor element 2 in this embodiment. The current sensor element 2 is battery powered and, to reduce battery power, is likely to be in a low power state most of the time. This low power state will include the wireless communications module being turned off. By having the current sensor element 2 send the synchronisation message it only needs to turn power on to the communications module when a synchronisation event is going to occur, or when the current sensor is transmitting the information it has measured about current flow, thus reducing unnecessary power consumption. In the first power monitoring system 1, the beginning of the synchronisation message is the synchronisation event, as shown in FIG. 4.

Although the system described only details a current sensor element and a voltage sensor element, there are embodiments that include other elements. A display element may be included to provide a visual representation of the power usage. This display element may be a separate part of the system or may be integrated with the voltage sensor element. As in any such distributed system, the processing needed to calculate power consumption can be performed in any of the system nodes. The description above details the calculations occurring in the voltage sensor element as a means of increasing the battery life of the current sensor element, and thus the system as a whole. There may be other embodiments where it is more appropriate to perform these calculations in the current sensor element, or in a third element of the system. Equally the timing synchronisation message can originate from any element of the system, as long as all elements can synchronise their timers to within the required accuracy.

The frequency with which the power is sampled by the first power monitoring system 1 can be adjusted using the controls 16 on the current sensor 2. Using these controls the user can set the frequency of the synchronisation events and measurements. The user can hence increase either the accuracy or the battery life of the first power monitoring system 1.

The information on power usage collected by the power monitoring system 1 can either be stored to later access on the voltage sensor 3 or transmitted to some other device, such as a personal computer, either directly using a wireless link or over the internet via a wireless modem.

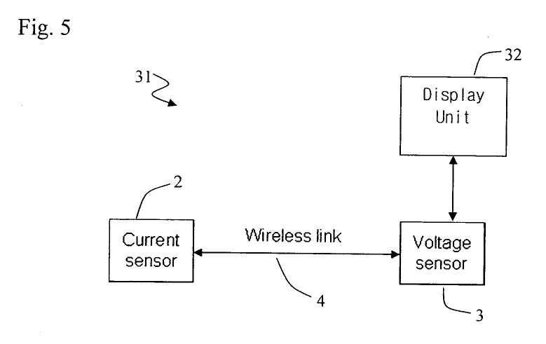

FIG. 5 shows a second power monitoring system 31 according to the invention. The second power monitoring system 31 comprises a current sensor 2 and a voltage sensor 3 as described above. The second power monitoring system 31 further comprises a separate display unit 32. The display unit 32 is also battery powered and can be placed anywhere that is convenient. When the user activates the display unit 31 it sends a wireless signal to the voltage sensor, prompting the voltage sensor 3 to respond with information about power usage that the display unit 32 will then display to the user. The display unit 31 can also be used to set the frequency of the synchronisation events and measurements made by the second power monitoring system 31. When the user adjusts this frequency, the display unit sends a wireless signal to the voltage sensor 3, which in turn waits until the next synchronisation signal is received from the current sensor 2. While the synchronisation signal is being transmitted the current sensor can also receive instructions wirelessly, and during this window the voltage sensor 3 transmits the instructions to change the frequency of the synchronisation events.

In order to conserve battery power, the display unit will not display information or communicate with the voltage sensor 3 until the user requests it.

In a third embodiment, a personal computer is used as a display unit for a power monitoring system according to the invention.

1-29. (canceled)

30. A power measurement system for providing power measurements comprising:
a current sensing element suitable for sensing current for time windows at a supply line location, the current sensing element comprising a first communication means;
a voltage sensing element suitable for sensing voltage for time windows; the voltage sensing element being physically separate from the current sensing element and located remotely from said supply line location, the voltage sensing element comprising a second communication means; and
a communication link between said first and second communication means;
wherein the communication link is a wireless communication link employed for synchronising the timing between current and voltage measurements; whereby said power measurement is enabled by synchronisation of said time windows over which the current and voltage measurements are sampled.

31. A system as claimed in claim 30, comprising means for transmitting a synchronisation message to said current and voltage sensing elements.

32. A system according to claim 30, wherein synchronisation is achieved by detecting one of the start and end of the transmission of a synchronisation message.

33. A system according to claim 30, wherein the system is configured to start a sampling window a predetermined time after a synchronisation event.

34. A system as claimed in claim 30, wherein the system comprises an additional separate element capable of communicating with one of the voltage sensing element, and the current sensing element.

35. A system as claimed in claim 34, wherein the timing between the current and voltage measurements is synchronised using a signal sent by the additional separate element.

36. A system as claimed in claim 35, wherein the additional separate element is configured to communicate wirelessly.

37. A system as claimed in claim 30, wherein the timing between the current and voltage measurements is synchronised using a signal sent by the current sensing element.

38. A system as claimed in claim 30, wherein the voltage sensing element is configured to calculate the power usage.

39. A system according to claim 30, wherein the current sensing element is configured to measure current periodically.

40. A system according to claim 30, wherein the voltage sensing element is configured to measure voltage periodically.

41. A system according to claim 30, wherein the voltage sensing element is configured to sample voltage periodically and the current sensing element is configured to measure current periodically; the voltage sensing element being configured to sample at a lower rate than the current sensing element.

42. A system according to claim 30, wherein current and voltage measurements are sampled at one of the group comprising: the same time, at a known gap, and at a measured time gap.

43. A method for providing power measurements, the method comprising providing a current sensing element and a voltage sensing element and:
measuring current for time windows at a supply line location;
measuring voltage for time windows at location physically separate from the current sensing element and located remotely from said supply line location; and
synchronising the time windows over which the measurements of current and voltage are sampled by wireless communication between current and voltage sensing elements.

44. A method as claimed in claim 43, comprising the step of transmitting a synchronisation message to said current and voltage sensing elements.

45. A method according to claim 43, comprising the step of detecting one of the start and end of the transmission of a synchronisation message.

46. A method according to claim 43, comprising the step of starting a sampling window a predetermined time after a synchronisation event.

47. A method according to claim 43, comprising the steps of providing an additional separate element; and communicating with one of the voltage sensing element and the current sensing element.

48. A method according to claim 47, comprising the step of synchronising the timing between the current and voltage measurements using a signal sent by the additional separate element.

49. A method according to claim 47, comprising the step of configuring the additional separate element to communicate wirelessly.

50. A method according to claim 43, comprising the step of synchronising the timing between the current and voltage measurements using a signal sent by the current sensing element.

51. A method according to claim 43, comprising the step of calculating the power usage in the voltage sensing element.

52. A method according to claim 43, comprising the step of measuring current periodically.

53. A method according to claim 43, comprising the step of measuring the voltage periodically.

54. A method according to claim 43, comprising the step of sampling voltage at a lower rate than current.

55. A method according to claim 43, comprising the step of sampling current and voltage measurements at one of the group: the same time, a known gap, and a measured time gap.

56. Computer software which configures components to operate according to the method of claim 43.

57. A power measurement system for providing power measurements comprising:
a current sensing element suitable for sensing current for time windows at a supply line location, the current sensing element comprising a first communication module;
a voltage sensing element suitable for sensing voltage for time windows; the voltage sensing element being physically separate from the current sensing element and located remotely from said supply line location, the voltage sensing element comprising a second communication module; and
a communication link between said first and second communication module;
wherein the communication link is a wireless communication link employed for synchronising the timing between current and voltage measurements; whereby said power measurement is enabled by synchronisation of said time windows over which the current and voltage measurements are sampled.
